(19) United States
(12) Patent Application Publication
(10) Pub. No.: US 2026/0361274 A1
(43) Pub. Date: Nov. 12, 2026

(54) INTERFACE CIRCUIT FOR A TRANSCEIVER

(71) Applicant: QUALCOMM Incorporated, San Diego, CA (US)

(72) Inventors: Alaaeldien Mohamed Abdelrazek MEDRA, San Diego, CA (US); Yunfei FENG, San Diego, CA (US)

(21) Appl. No.: 19/205,780

(22) Filed: May 12, 2025

(51) Int. Cl. H03F 1/26; H03F 3/24

(52) U.S. Cl. CPC H03F 1/26; H03F 3/245; H03F 2200/294

(57) ABSTRACT

An apparatus includes a power amplifier (PA), a low-noise amplifier (LNA), and an interface circuit configured to couple an antenna to the PA and the LNA. The interface circuit includes a transformer circuit configured to magnetically couple an output of the PA to the antenna, an input inductor coupled in series between the antenna and an input of the LNA, and a switch configured to selectively couple the input of the LNA to a leakage inductor.

### BACKGROUND

### Field

Aspects of the present disclosure relate generally to wireless communications, and, more particularly, to an interface circuit for a transceiver.

### Background

A wireless device includes a transceiver for transmitting and receiving radio frequency (RF) signals via one or more antennas. The transceiver may include a power amplifier (PA) configured to amplify an RF signal for transmission via an antenna, and a low-noise amplifier (LNA) configured to amplify an RF signal received by the antenna. The transceiver may also include an interface circuit configured to couple the PA and the LNA to the antenna.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to an apparatus. The apparatus includes a power amplifier (PA), a low-noise amplifier (LNA), and an interface circuit configured to couple an antenna to the PA and the LNA. The interface circuit includes a transformer circuit configured to magnetically couple an output of the PA to the antenna, an input inductor coupled in series between the antenna and an input of the LNA, and a switch configured to selectively couple the input of the LNA to a leakage inductor.

A second aspect relates to an interface circuit for a transceiver having an antenna, a power amplifier (PA), and a low-noise amplifier (LNA). The interface circuit includes a transformer circuit including a shunt inductor coupled to the antenna, and an output inductor for magnetically coupling an output of the PA to the shunt inductor. The interface circuit also includes an input inductor coupled in series between the antenna to an input of the LNA, and a switch for selectively coupling a leakage inductor to the input of the LNA.

A third aspect relates to a method of operating a transceiver. The transceiver includes an antenna, a power amplifier (PA), a low-noise amplifier (LNA), and an interface circuit coupling the antenna to the PA and the LNA, wherein the interface circuit includes a transformer circuit magnetically coupling an output of the PA to the antenna, an input inductor coupling the antenna in series to an input of the LNA, and a switch selectively coupling the input of the LNA to a leakage inductor. The method includes, during a transmit mode, coupling the input of the LNA to the leakage inductor using the switch, amplifying a first radio frequency (RF) signal to the output of the PA using the PA, and magnetically coupling the amplified first RF signal from the output of the PA to the antenna using the transformer circuit. The method also includes, during a receive mode, decoupling the input of the LNA from the leakage inductor using the switch, coupling a second RF signal in series from the antenna to the input of the LNA using the input inductor, and amplifying the second RF signal from the input of the LNA using the LNA.

### BRIEF DESCRIPTION OF THE DRAWINGS

FIG. 1 shows an example of a transceiver coupled to an antenna according to certain aspects of the present disclosure.

FIG. 2 shows an example of an interface circuit including a multi-coil transformer according to certain aspects of the present disclosure.

FIG. 3 shows an example of an interface circuit including a multi-coil circuit and a controller according to certain aspects of the present disclosure.

FIG. 4A shows an example of an equivalent circuit of the interface circuit of FIG. 3 in a receive mode according to certain aspects of the present disclosure.

FIG. 4B shows an example of an equivalent circuit of the interface circuit of FIG. 3 in a transmit mode according to certain aspects of the present disclosure.

FIG. 5 shows an example implementation of a switch in the interface circuit of FIG. 3 according to certain aspects of the present disclosure.

FIG. 6 shows a top view of an example layout of three inductors of the multi-coil circuit of FIG. 5 according to certain aspects of the present disclosure.

FIG. 7 shows an example implementation of an LNA according to certain aspects of the present disclosure.

FIG. 8 shows an example of an impedance-matching inductor in series between an antenna and an LNA according to certain aspects of the present disclosure.

FIG. 9 shows an example implementation of a switched source degeneration inductor of an LNA according to certain aspects of the present disclosure.

FIG. 10 shows another example implementation of a switched source degeneration inductor of an LNA according to certain aspects of the present disclosure.

FIG. 11A shows an example of a first mixer coupled to a PA and a second mixer coupled to an LNA according to certain aspects of the present disclosure.

FIG. 11B shows an example of an intermediate frequency (IF) circuit coupled to the first mixer of FIG. 11A according to certain aspects of the present disclosure.

FIG. 12A shows an example of a wireless device including multiple antennas and multiple interface circuits according to certain aspects of the present disclosure.

FIG. 12B shows another example of a wireless device including multiple antennas and multiple interface circuits according to certain aspects of the present disclosure.

FIG. 13 is a diagram of an environment including an electronic device that includes a transceiver according to certain aspects of the present disclosure.

FIG. 14 is a flowchart illustrating a method of operating a transceiver according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. In the drawings, like-numbered elements represent the same or functionally similar components between the different illustrated embodiments. Accordingly, their corresponding descriptions are not necessarily repeated for each of their corresponding drawings.

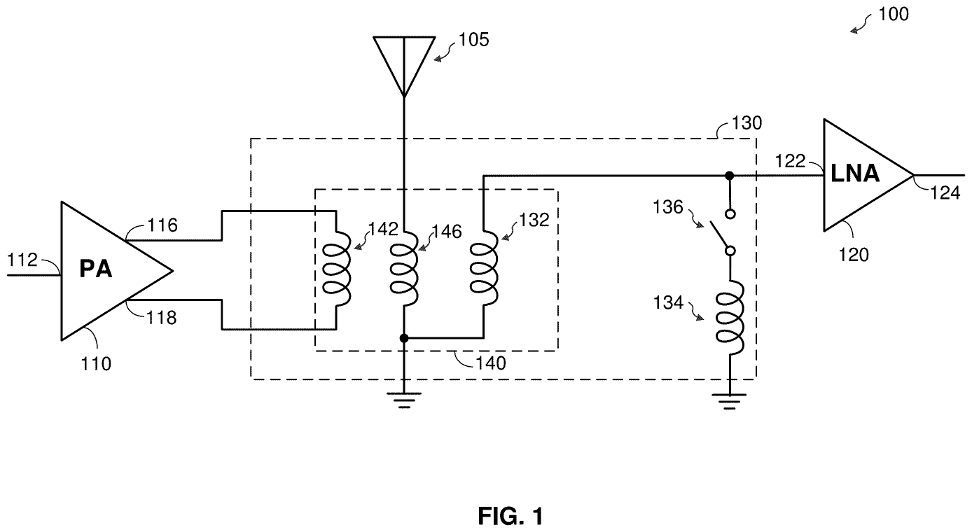

FIG. 1 shows an example of a wireless device 100 according to certain aspects. The wireless device 100 includes a power amplifier (PA) 110, a low-noise amplifier (LNA) 120, an interface circuit 130, and an antenna 105. The PA 110 and the LNA 120 may be part of a transceiver configured to transmit and receive radio frequency (RF) signals via one or more antennas including the antenna 105. The PA 110 is configured to amplify an RF signal for transmission via the antenna 105 and the LNA 120 is configured to amplify an RF signal received by the antenna 105. The interface circuit 130 is configured to couple the PA 110 and the LNA 120 to the antenna 105. Although one PA 110, one LNA 120, and one antenna 105 are shown in FIG. 1, it is to be appreciated that the wireless device 100 may include multiple PAs, multiple LNAs, and multiple antennas.

In certain aspects, the PA 110 and the LNA 120 may be configured to transmit and receive RF signals in the millimeter wave (mmWave) band (e.g., above 24 GHz, such as between 30 GHz and 300 GHz), which supports high data rates. Operating in the mmWave band allows the use of small antennas, which allow the wireless device 100 to employ one or more antenna arrays (e.g., for high directivity and antenna gain). However, it is to be appreciated that the present disclosure is not limited to the mmWave band.

In the example in FIG. 1, the PA 110 is a differential power amplifier having an input 112 and a differential output, in which the differential output includes a first output 116 and a second output 118. In this example, the PA 110 is configured to receive an RF signal at the input 112 (e.g., from a mixer or another circuit), amplify the RF signal, and output the amplified RF signal at the differential output. In certain aspects, the PA 110 may be implemented with two or more amplifiers. The input 112 may be, for example, a single-ended input or a differential input.

The LNA 120 has an input 122 and an output 124. The LNA 120 is configured to receive an RF signal at the input 122, amplify the received RF signal, and output the amplified RF signal at the output 124. The output 124 may be coupled to a mixer for frequency down-conversion, a phase shifter, a variable amplifier, an attenuator, and/or one or more other circuits in the transceiver. The output 124 may be, for example, a single-ended output or a differential output.

In the example in FIG. 1, the interface circuit 130 includes a transformer 140 (e.g., tricoil transformer), a leakage inductor 134, and a switch 136. The transformer 140 includes a first inductor 142 (such as a PA output inductor), a second inductor 146 (such as an antenna shunt inductor), and a third inductor 132. The inductors 142, 146, and 132 are magnetically (i.e., inductively) coupled with one another. The first inductor 142 is coupled between the first output 116 and the second output 118 of the PA 110, the second inductor 146 is coupled between the antenna 105 and a ground (or some reference potential), and the third inductor 132 is coupled between the input 122 of the LNA 120 and the ground (or some reference potential). The transformer 140 is used to provide impedance matching between the differential output of the PA 110 and the antenna 105. The transformer 140 may also transform the differential RF signal at the first inductor 142 into a single-ended RF signal at the second inductor 146 for transmission by the antenna 105.

The leakage inductor 134 is selectively coupled between the input 122 of the LNA 120 and the ground (or reference voltage), as well selectively coupled in a loop with the third inductor 132, as controlled by the switch 136. The switch 136 is coupled between the input 122 of the LNA 120 and the leakage inductor 134, as well as between the third inductor 132 and the leakage inductor 134. When the switch 136 is open, the leakage inductor 134 is decoupled from the LNA input signal path. When the switch 136 is closed, the leakage inductor 134 is coupled with the third inductor 132 in a loop. As discussed further below, when the switch 136 is closed, the leakage inductor 134 reduces the coupling loss from the PA 110 to the LNA 120 (i.e., reduces the PA power leakage to the LNA 120), which increases the coupling of the PA output signal to the antenna 105. The leakage inductor 134 also helps provide impedance matching between the output of the PA 110 and the antenna 105.

In certain aspects, the wireless device 100 may transmit an RF signal via the antenna 105 and receive an RF signal via the antenna 105 one at a time using a time division duplex (TDD) protocol. In these aspects, the wireless device 100 transmits an RF signal via the antenna 105 in a transmit mode and receives an RF signal via the antenna 105 in a receive mode, where the transmit mode and the receive mode alternate or otherwise avoid overlapping because of the TDD protocol.

In the transmit mode, a controller (not shown) turns on (i.e., closes) the switch 136, which couples the leakage inductor 134 to the third inductor 132. The PA 110 receives an RF signal to be transmitted (e.g., from a mixer or another circuit), amplifies the RF signal, and outputs the amplified RF signal to the transformer 140. The transformer 140 couples the amplified RF signal to the antenna 105 for transmission via magnetic coupling between the first inductor 142 and the second inductor 146. The leakage inductor 134 (which is outside of the transformer 140 and coupled to the third inductor 132) reduces the effective coupling factor between the first inductor 142 and the third inductor 132 in the transmit mode. This reduces the coupling loss from the PA 110 to the LNA 120, which increases the coupling of the PA output signal to the antenna 105. The leakage inductor 134 also helps provide impedance matching between the output of the PA 110 and the antenna 105. For example, the inductance of the leakage inductor 134 may be chosen to provide a load impedance at the output of the PA 110 that provides good impedance matching.

In the receive mode, the controller (not shown) turns off (i.e., opens) the switch 136, which decouples the leakage inductor 134 from the input signal path of the LNA 120. As a result, the leakage inductor 134 has little to no effect on the LNA 120 in the receive mode. In the receive mode, the antenna 105 receives an RF signal (e.g., from a base station or another device). The transformer 140 couples the received RF signal to the input 122 of the LNA 120 through magnetic coupling between the second inductor 146 and the third inductor 132. The LNA 120 amplifies the received RF signal and outputs the amplified RF signal at the output 124. The amplified RF signal may be output to a mixer (not shown) for frequency down-conversion and/or one or more other circuits in the transceiver.

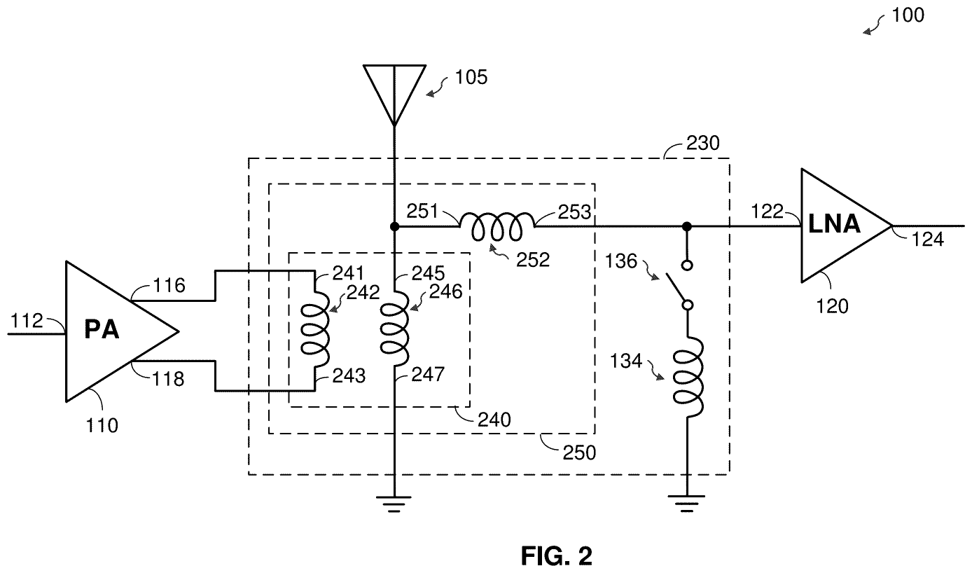

A challenge with the interface circuit 130 is that the interface circuit 130 increases the noise figure of the LNA 120 due to signal loss in the interface circuit 130 in the receive mode. The noise figure may be improved by replacing the third inductor 132 with a series inductor coupled between the antenna 105 and the input 122 of the LNA 120, as discussed further below with reference to FIG. 2.

FIG. 2 shows another example implementation of an interface circuit 230 according to certain aspects. In this example, the interface circuit 230 includes a multi-coil transformer 250 (e.g., a tricoil transformer or tricoil circuit) in place of the transformer 140 shown in FIG. 1. The multi-coil transformer 250 includes a PA transformer 240 and a third inductor 252, which may all be in a common package (e.g., an integrated circuit chip or area of close proximity, such as within significant magnetic coupling range). In this example, the third inductor 252 is coupled in series between the antenna 105 and the input 122 of the LNA 120, and may therefore also be referred to as a series inductor. The PA transformer 240 couples the PA 110 to the antenna 105 and the third inductor 252 couples the antenna 105 to the LNA 120, as discussed further below.

In the example in FIG. 2, the multi-coil transformer 250 includes the PA transformer 240 (including a first inductor 242 and a second inductor 246) and the third inductor 252 (or series inductor). The first inductor 242 (or PA output inductor) is coupled between the first output 116 and the second output 118 of the PA 110, the second inductor 246 (or shunt inductor) is coupled between the antenna 105 and a ground (or some reference potential), and the third inductor 252 is coupled in series between the antenna 105 and the input 122 of the LNA 120. In the example in FIG. 2, the first inductor 242 has a first terminal 241 coupled to the first output 116 of the PA 110 and a second terminal 243 coupled to the second output 118 of the PA 110. The second inductor 246 has a first terminal 245 coupled to the antenna 105 and a second terminal 257 coupled to the ground. The third inductor 252 has a first terminal 251 coupled to the antenna 105 and a second terminal 253 coupled to the input 122 of the LNA 120.

The first inductor 242 and the second inductor 246 are magnetically (i.e., inductively) coupled. Because of their proximity, there is also magnetic coupling between the third inductor 252 (or series inductor) and each of the first inductor 242 and the second inductor 246. Each of the first inductor 242, the second inductor 246, and the third inductor 252 may be implemented with a coil inductor, a spiral inductor, a loop inductor, a slab inductor, or another type of inductor. It is to be appreciated that each of the first inductor 242, the second inductor 246, and the third inductor 252 may be referred to as a coil even in cases where the inductors are not physically implemented with coils. In the example in FIG. 2, the multi-coil transformer 250 is shown as a tricoil transformer (or tricoil circuit or tricoil) including three magnetically coupled inductors (i.e., the first inductor 242, the second inductor 246, and the third inductor 252). However, it is to be appreciated that the multi-coil transformer 250 is not limited to this example and may include more than three inductors.

In this example, the interface circuit 230 also includes the switch 136 and the leakage inductor 134 of like name and function to the corresponding components of the interface circuit 130 of FIG. 1.

As discussed above, the wireless device 100 may employ TDD, in which the wireless device 100 transmits an RF signal via the antenna 105 in the transmit mode and receives an RF signal via the antenna 105 in the receive mode.

In the transmit mode, a controller (not shown) turns on (i.e., closes) the switch 136, which couples the leakage inductor 134 to the third inductor 252 (or series inductor). The PA 110 receives an RF signal to be transmitted (e.g., from a mixer or another circuit), amplifies the RF signal, and outputs the amplified RF signal to the transformer 240. The PA transformer 240 couples the amplified RF signal to the antenna 105 for transmission via magnetic coupling between the first inductor 242 and the second inductor 246. The leakage inductor 134 (which is outside of the transformer 240 and coupled to the third inductor 252) reduces the effective coupling factor between the first inductor 242 and the third inductor 252 in the transmit mode. This reduces the coupling loss from the PA 110 to the LNA 120 (i.e., reduces the PA power leakage to the LNA 120), which increases the coupling of the PA output signal to the antenna 105. As discussed further below, the coupling factor may be further reduced by implementing the third inductor 252 with a figure-eight shape.

In the receive mode, the controller (not shown) turns off (i.e., opens) the switch 136, which decouples the leakage inductor 134 from the input signal path of the LNA 120. In the receive mode, the antenna 105 receives an RF signal (e.g., from a base station or another device). The third inductor 252 (or series inductor) couples the received RF signal to the input 122 of the LNA 120. The LNA 120 amplifies the received RF signal and outputs the amplified RF signal at the output 124. The amplified RF signal may be output to a mixer (not shown) for frequency down-conversion and/or one or more other circuits in the transceiver. In this example, the third inductor 252 reduces signal loss between the antenna 105 and the LNA 120 compared with the third inductor 132 (or shunt inductor) in FIG. 1. This is because the third inductor 252 can be directly coupled to the antenna 105 while the third inductor 132 is magnetically coupled to the antenna 105, which introduces signal loss.

In the receive mode, the second inductor 246 (or shunt inductor) and the third inductor 252 (or series inductor) form a shunt-series impedance matching network for the LNA 120. In this example, the inductance of the third inductor 252 may be chosen to provide good impedance matching for the LNA 120. Since the leakage inductor 134 is decoupled from the input signal path of the LNA 120 in the receive mode, the inductance of the leakage inductor 134 has little to no effect on the impedance matching for the LNA 120, allowing the third inductor 252 to be independently tuned to optimize impedance matching for the LNA 120.

Thus, the multi-coil transformer 250 couples the PA 110 to the antenna 105 and couples the antenna 105 to the LNA 120. In addition, the multi-coil transformer 250 reduces the area of the interface circuit 230 compared with using a series inductor outside of the multi-coil transformer 250. This is because the multi-coil transformer 250 allows the third inductor 252 to be placed in close proximity to the inductors 242 and 246 (e.g., overlap the inductors 242 and 246 or placed within the inductors 242 and 246) to save area compared with placing the third inductor 252 outside of the multi-coil transformer 250. However, a challenge with using the multi-coil transformer 250 in the interface circuit 230 is that PA performance and LNA performance may be impacted, as discussed further below.

A low coupling factor k between the third inductor 252 and the first inductor 242 (of the PA transformer 240) is desirable for LNA performance, where the coupling factor k is a measure of magnetic coupling. This is because a low coupling factor k reduces loss between the antenna 105 and the LNA 120, which improve the noise figure of the LNA 120.

A low coupling factor k between the first inductor 242 and the third inductor 252 is also desirable for PA performance. This is because the third inductor 252 loads the PA 110 (due to its proximity to the first inductor 242 in the multi-coil transformer 250), which reduces the amount of power that the PA transformer 240 transfers from the PA 110 to the antenna 105. The higher the coupling factor k between the first inductor 242 and the third inductor 252, the greater the load from the third inductor 252 and therefore the greater the loss between the PA 110 and the antenna 105.

A challenge with designing the multi-coil transformer 250 is that locating the third inductor 252 in close proximity to the first inductor 242 and the second inductor 246 to save area runs the risk of increasing the coupling factor k between the first inductor 242 and the third inductor 252, which can degrade the noise figure of the LNA 120 and increase the loss between the PA 110 and the antenna 105. Thus, there is a possible trade-off for reducing area of the interface circuit 230 and achieving high performance for both the PA 110 and the LNA 120.

The leakage inductor 134 on the receive side helps reduce the coupling factor k between the first inductor 242 and the third inductor 252 in the transmit mode. As discussed above, the leakage inductor 134 is switchable between the transmit mode and the receive mode by the switch 136. In the transmit mode, the switch 136 couples the leakage inductor 134 to the third inductor 252 of the multi-coil transformer 250, which reduces the effective coupling factor k between the first inductor 242 and the third inductor 252 in the transmit mode, and therefore reduces the loss between the PA 110 and the antenna 105 in the transmit mode for improved PA performance. In the receive mode, the switch 136 decouples the leakage inductor 134 from the third inductor 252 of the multi-coil transformer 250 so that the leakage inductor 134 has little to no effect on the impedance matching for the LNA 120 in the receive mode.

In addition, as will be discussed in further detail below, aspects of the present disclosure implement the series-coupled third inductor 252 using a symmetric layout in the multi-coil transformer 250 to minimize or even cancel out the magnetic coupling effects of the first inductor 242 and the second inductor 246 on the third inductor 252. This reduces the coupling loss from the PA 110 to the LNA 120 (i.e., reduces the PA power leakage to the LNA 120).

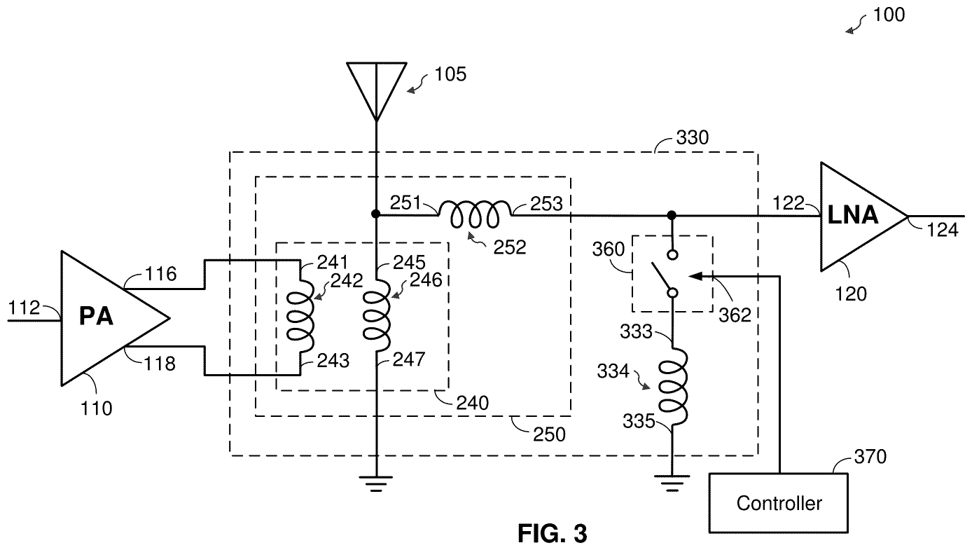

FIG. 3 shows an example interface circuit 330 according to certain aspects of the present disclosure. The interface circuit 330 includes the multi-coil transformer 250 having the PA transformer 240 and the third inductor 252 discussed above. The interface circuit 330 also includes a leakage inductor 334 and a switch 360. The switch 360 is coupled between the input 122 of the LNA 120 and a first terminal 333 of the leakage inductor 334. leakage inductor 334 has a second terminal 335 coupled to a ground (or some reference potential). The leakage inductor 334 may correspond to the leakage inductor 134 and the switch 360 may correspond to the switch 136 discussed above.

In this example, the wireless device 100 also includes a controller 370 coupled to a control input 362 of the switch 360. As used herein, a “control input” of a switch controls the on/off state of the switch based on a control signal (e.g., voltage or current) input to the control input. As discussed further below, the controller 370 is configured to control the on/off state of the switch 360 via the control input 362.

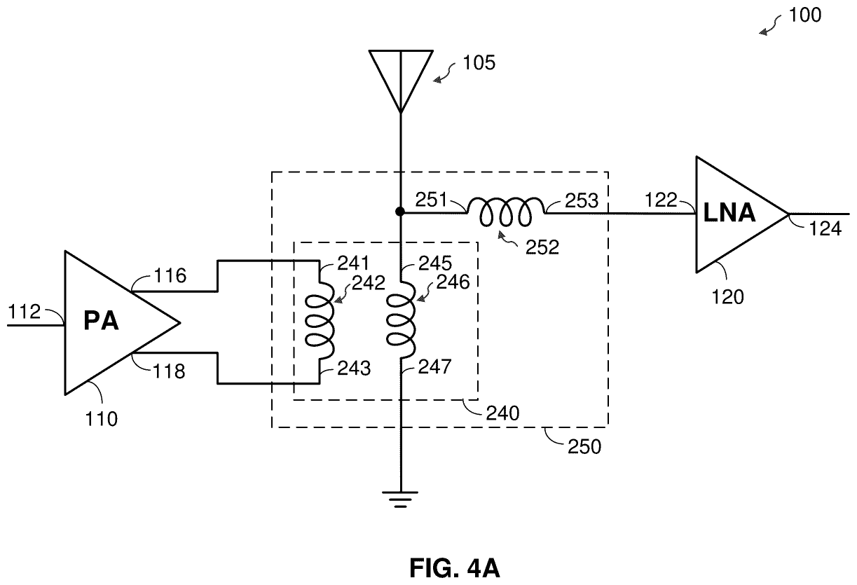

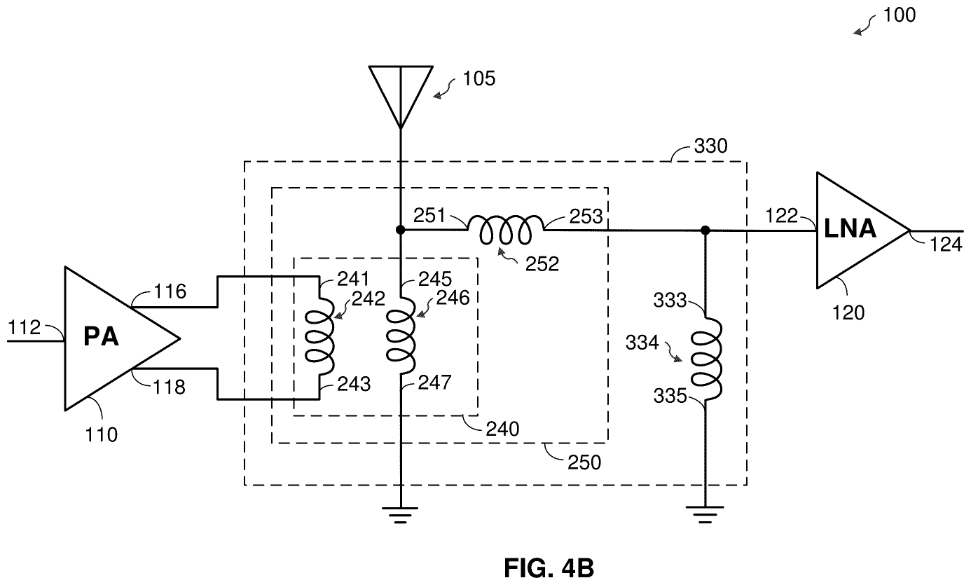

In the receive mode, the controller 370 turns off (i.e., opens) the switch 360 via the control input 362. As a result, the switch 360 decouples the leakage inductor 334 from the input 122 of the LNA 120. FIG. 4A shows an example of an equivalent circuit of the interface circuit 330 in the receive mode. As shown in FIG. 4A, decoupling the leakage inductor 334 from the input 122 of the LNA 120 effectively removes the leakage inductor 334 so that the leakage inductor 334 has little to no effect on the impedance matching for the LNA 120 in the receive mode. This allows the LNA 120 to achieve improved performance.

In the transmit mode, the controller 370 turns on (i.e., closes) the switch 360 via the control input 362. As a result, the switch 360 couples the third inductor 252 to the leakage inductor 334. The switch 360 also couples the leakage inductor 334 between the input 122 of the LNA 120 and the ground.

FIG. 4B shows an example of an equivalent circuit of the interface circuit 330 in the transmit mode. As shown in FIG. 4B, the leakage inductor 334 is coupled to the third inductor 252 of the multi-coil transformer 250. More particularly, the first terminal 333 of the leakage inductor 334 is coupled to the second terminal 253 of the third inductor 252. Because the leakage inductor 334 is outside the multi-coil transformer 250 (e.g., tricoil transformer), coupling the leakage inductor 334 to the third inductor 252 reduces the effective coupling factor k between the first inductor 242 and the third inductor 252 in the transmit mode, and therefore reduces the loss between the PA 110 and the antenna 105 in the transmit mode for improved PA performance. Thus, the LNA 120 achieves high performance in the receive mode while the PA 110 achieves high performance in the transmit mode.

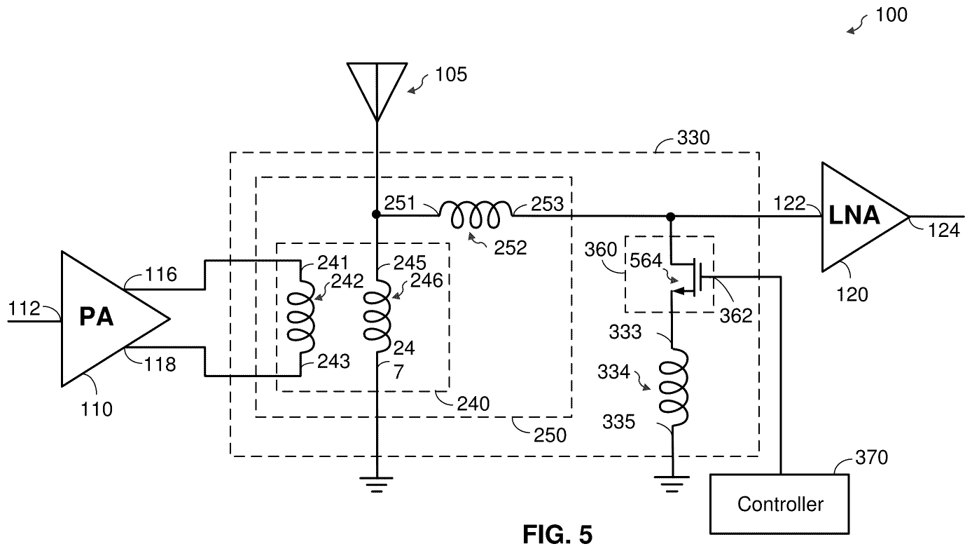

FIG. 5 shows an example implementation of the switch 360 according to certain aspects. In this example, the switch 360 includes a transistor 564, in which the drain of the transistor 564 is coupled to the input 122 of the LNA 120, the source of the transistor 564 is coupled to the first terminal 333 of the leakage inductor 334, and the gate of the transistor 564 is coupled to the control input 362 of the switch 360. In the example shown in FIG. 5, the transistor 564 is implemented with an n-type field effect transistor (NFET). However, it is to be appreciated that the transistor 564 is not limited to this example and may be implemented with another type of transistor in other implementations. For the example where the transistor 564 is implemented with the NFET, the controller 370 may turn off the switch 360 by coupling the gate of the transistor 564 to the ground and turn on the switch 360 by outputting a voltage to the gate of the transistor 564 exceeding the threshold voltage of the transistor 564. It is to be appreciated that the switch 360 is not limited to this example. In other examples, the switch 360 may include a transmission gate, or another type of switch.

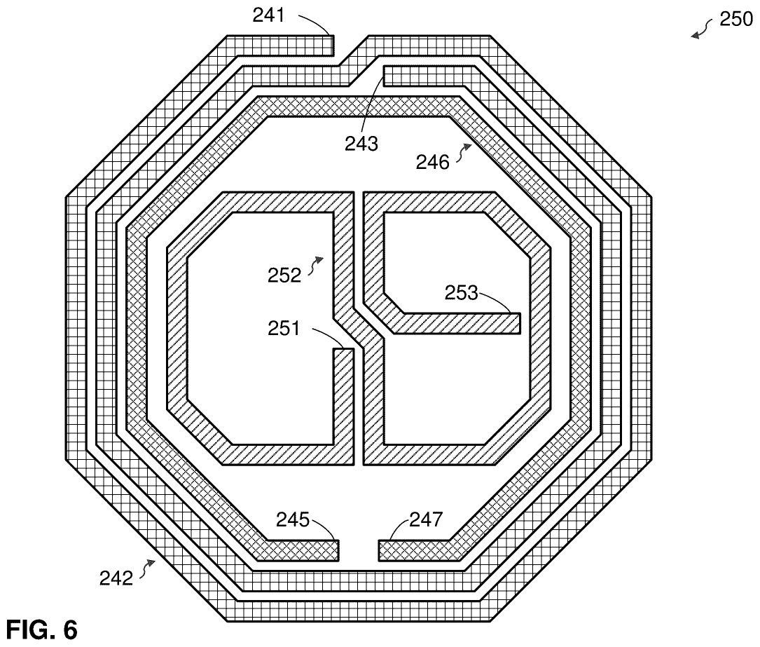

FIG. 6 shows a top view of an example layout of the three inductors of the multi-coil transformer 250 of FIG. 5 according to certain aspects of the present disclosure. For ease of illustration, only non-overlapping portions of the multi-coil transformer 250 are illustrated in FIG. 6. As such, the layout could be implemented in a single metal layer (or conductive layer) of the multi-coil transformer 250, though other aspects are not so limited. In addition, overlapping portions from other metal layers can be added to the layout to, for example, connect the illustrated portions to other signal lines or reference potentials of the multi-coil transformer 250.

In the layout of FIG. 6, the first inductor 242 has an encompassing shape (octagonal, in this case) extending to a periphery of the multi-coil transformer 250, with ends corresponding to the first terminal 241 and the second terminal 243. Likewise, the second inductor 246 has an encompassing shape (also octagonal) extending to and inside that of (such as surrounded by) the first inductor 242, with ends corresponding to the first terminal 245 and the second terminal 247.

Finally, the third inductor 252 has a symmetric shape (figure-eight, in this case) extending to and inside that of (such as surrounded by) the second inductor 246), with ends corresponding to the first terminal 251 and the second terminal 253. In further detail, the symmetric shape of the third inductor 252 is configured to cancel out the magnetic coupling effects of the surrounding the first inductor 242 and the second inductor 246. In other words, the magnetic coupling effects from the first inductor 242 and the second inductor 246 with any electrical signal flowing clockwise through a portion of the third inductor 252 are substantially offset or canceled by the same electrical signal flowing counterclockwise through a different portion of the third inductor 252. The figure-eight layout shown, for example, has two similar portions of the third inductor 252. As such, any electrical signal that flows counterclockwise in one portion of the figure eight will flow clockwise in the other portion, and with enough geometric symmetry in and between the three inductors the magnetic coupling effects on the third inductor 252 from the first inductor 242 and the second inductor 246 are effectively canceled out. This cancellation effect reduces the effective coupling factor k between first inductor 242 and the third inductor 252, and therefore reduces the PA output leakage to the LNA 120 through the third inductor 252.

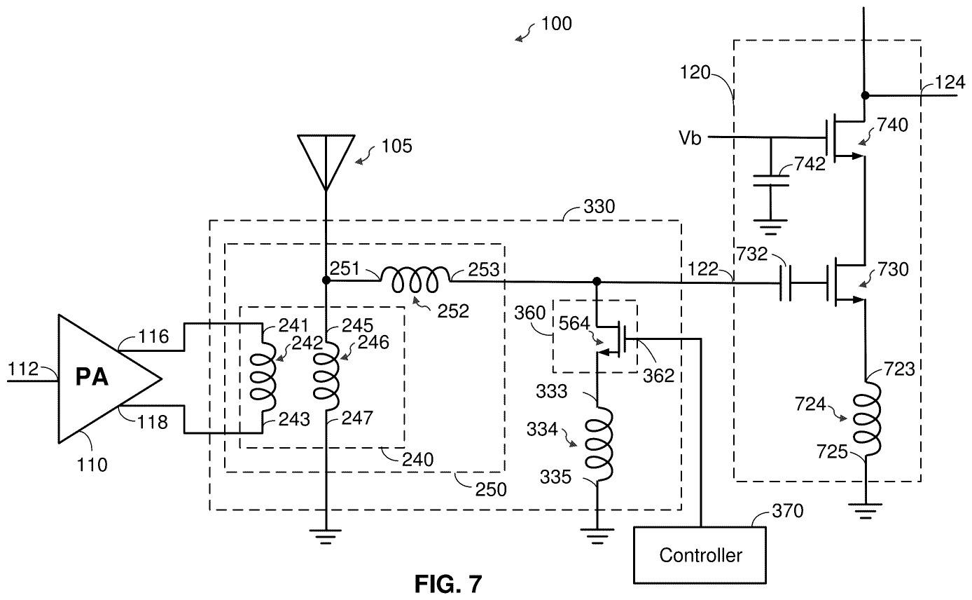

FIG. 7 shows an example implementation of the LNA 120 according to certain aspects. In this example, the LNA 120 includes a first transistor 730, a second transistor 740, and source degeneration inductor 724. In the example shown in FIG. 7, the first transistor 730 is implemented with a first NFET and the second transistor 740 is implemented with a second NFET. However, it is to be appreciated that the first transistor 730 and the second transistor 740 are not limited to this example.

In this example, the gate of the first transistor 730 is coupled to the input 122 of the LNA 120 through coupling capacitor 732, and the source degeneration inductor 724 is coupled between the source of the first transistor 730 and the ground. The source degeneration inductor 724 has first terminal 723 coupled to the source of the first transistor 730 and a second terminal 725 coupled to the ground. The gate of the second transistor 740 is biased by a bias voltage Vb, the source of the second transistor 740 is coupled to the drain of the first transistor 730, and the drain of the second transistor 740 is coupled to the output 124 of the LNA 120. In the example in FIG. 7, the LNA 120 includes a capacitor 742 coupled between the gate of the second transistor 740 and the ground. For example, the capacitor 742 may be used for voltage stabilizing of the bias line and provide an AC ground at the gate of the second transistor 740. The LNA 120 may also include a load (not shown) coupled between a supply rail and the output 124 of the LNA 120. The load may include a resistor, a capacitor, an inductor, or any combination thereof.

In this example, the first transistor 730 acts as a common-source amplifier with source degeneration provided by the source degeneration inductor 724. The second transistor 740 acts as a common-gate amplifier that provides a high impedance at the drain of the second transistor 740 for high gain. Together, the first transistor 730 and the second transistor 740 implement a cascode amplifier.

It is to be appreciated that the LNA 120 is not limited to the example shown in FIG. 7. For example, in some implementations (e.g., non-cascode amplifier), the second transistor 740 may be omitted with the drain of the first transistor 730 coupled to the output 124 of the LNA 120. It is to be appreciated that the LNA 120 may include one or more additional elements not shown in FIG. 7. It is also to be appreciated that one or more elements shown in the example in FIG. 7 may be omitted in some implementations.

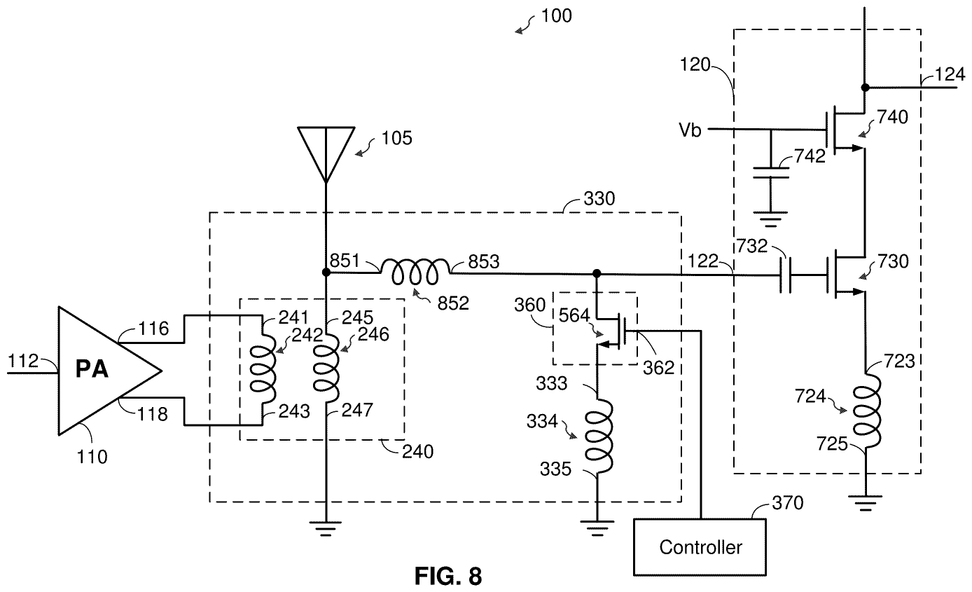

FIG. 8 shows another example implementation in which the interface circuit 330 includes an impedance-matching inductor 852 that is not part of a multi-coil transistor (e.g., the multi-coil transformer 250 shown in FIG. 7) with the inductors 242 and 246. For example, the impedance-matching inductor 852 may be located away from the inductors 242 and 246 of the PA transformer 240 such that the impedance-matching inductor 852 is not located within the inductors 242 and 246 and does not overlap the inductor 242 and 246.

In this example, the impedance-matching inductor 852 is separate from the transformer 240 and not part of a multi-coil transformer. For instance, the impedance-matching inductor 852 is magnetically separated from the transformer 240, such that any magnetic coupling between the impedance-matching inductor 852 and the transformer 240 is negligible or nonexistent. This reduces the coupling loss from the PA 110 to the LNA 120 (i.e., reduces PA power leakage to the LNA 120), which increases the coupling of the PA output signal to the antenna 105 in the transmit mode. Since the impedance-matching inductor 852 is implemented outside of the transformer 240 in this example, the impedance-matching inductor 852 does not need a figure-eight shape to reduce unwanted magnetic coupling and can therefore be implemented with a shape (e.g., octagonal shape) having an improved quality (Q) factor. The improved Q factor improves the noise figure of the LNA 120. Additionally, separating the impedance-matching inductor 852 from the transformer 240 allows independent improvements to the design and layout of the transformer 240 and LNA series matching. The impedance-matching inductor 852 includes a first terminal 851 coupled to the antenna 105 and a second terminal 853 coupled to the input 122 of the LNA 120 and selectively coupled to the leakage inductor 334 through the switch 360.

In the transmit mode, the controller 370 closes the switch 360, and, in the receive mode, the controller 370 opens the switch 360. In the mode receive mode, the impedance-matching inductor 852 is coupled in series between the antenna 105 and the input 122 of the LNA 120 to provide impedance matching between the antenna 105 and the input 122 of the LNA 120. In this example, the second inductor 246 (or shunt inductor) and the impedance-matching inductor 852 (or series inductor) form a shunt-series impedance matching network for the LNA 120 in the receive node. The inductance of the impedance-matching inductor 852 may be chosen to provide good impedance matching for the LNA 120 in the receive mode. Since the leakage inductor 334 is decoupled from the input signal path of the LNA 120 in the receive mode, the inductance of the leakage inductor 334 has little to no effect on the impedance matching for the LNA 120.

While making the impedance-matching inductor 852 separate from the transformer 240 and not part of a multi-coil transformer improves performance of the PA 110 and the LNA 120, this also comes with an area penalty since locating the impedance-matching inductor 852 away from the inductors 242 and 246 such that the impedance-matching inductor 852 is not located within the inductors 242 and 246 and does not overlap the inductor 242 and 246 consumes more area.

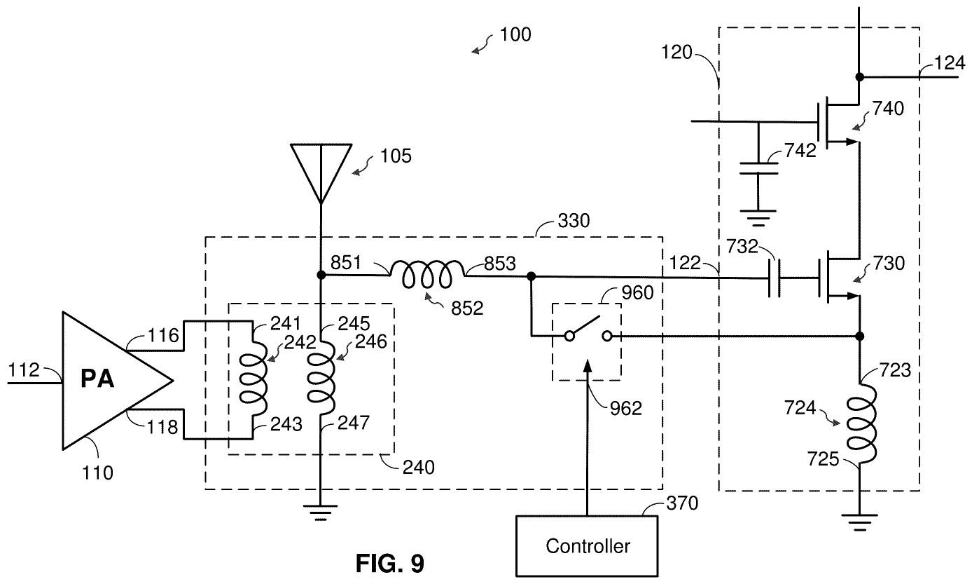

FIG. 9 shows an example implementation of a switched source degeneration inductor 724 of the LNA 120 according to certain aspects. To help save area and make more efficient use of the components of the wireless device 100, the interface circuit 330 of FIG. 8 is modified to omit the leakage inductor 334 and replace it with the source degeneration inductor 724 of the LNA 120. This reduces the number of components and saves area by using the same inductor (i.e., the source degeneration inductor 724) for both source degeneration in the receive mode and to perform the function of the leakage inductor 334 discussed above in the transmit mode. The area savings may be used to offset the area penalty incurred by making the impedance-matching inductor 852 separate from the transformer 240 and not part of a multi-coil transformer.

In the example shown in FIG. 9, the interface circuit 330 includes a switch 960 coupled between the input 122 of the LNA 120 and the first terminal 723 of the source degeneration inductor 724. The switch 960 is also coupled between the second terminal 853 of the impedance-matching inductor 852 and the first terminal 723 of the source degeneration inductor 724. The on/off state of the switch 960 is controlled by the controller 370 through a control input 962. The switch 960 may be implemented with a transistor (e.g., the transistor 564) or another type of switch. For the example of the transistor, the transistor may be implemented with an n-type field effect transistor (NFET) or another type of transistor.

In the transmit mode, the controller 370 turns on (i.e., closes) the switch 960 to couple the source degeneration inductor 724 to the impedance-matching inductor 852. In this mode, the source degeneration inductor 724 performs the function of the leakage inductor 334 discussed above. In the receive mode, the controller 370 turns off (i.e., opens) the switch 960. In this mode, the source degeneration inductor 724 provides the LNA 120 with source degeneration (e.g., to improve linearity and matching of the LNA 120).

In some aspects, the source degeneration inductor 724 includes a tunable inductor value for minimizing the PA load loss. For example, during the transmit mode, the inductor value of the source degeneration inductor 724 may be set to a value that reduces the PA load loss, while during the receive mode, the inductor value of the source degeneration inductor 724 may be set to a value that optimizes the performance of the LNA 120. In some aspects, the inductor value may be set to a single value for both transmit mode and receive mode (e.g., a value that provides good performance for both the PA 110 and the LNA 120).

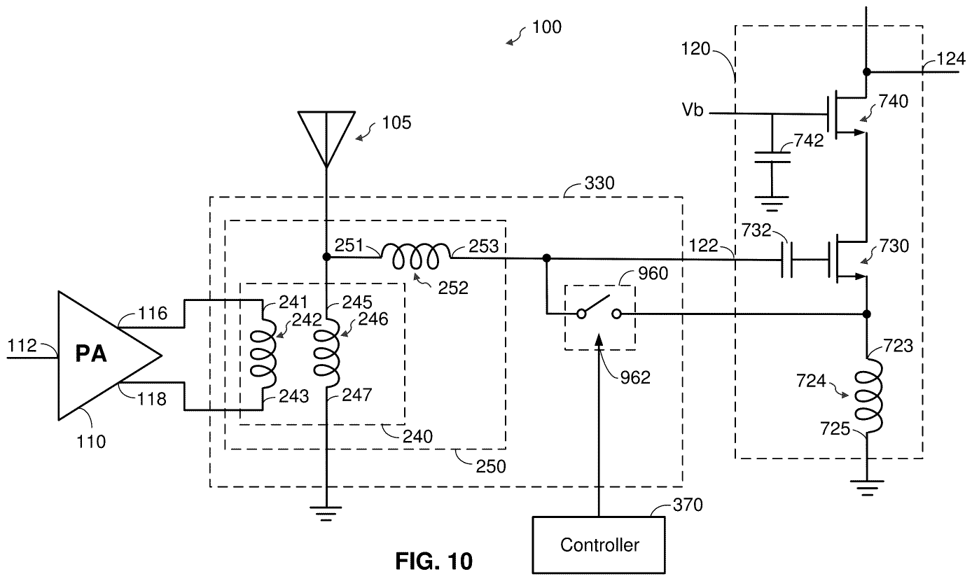

FIG. 10 shows another example implementation of the switched source degeneration inductor 724 of the LNA 120 according to certain aspects. In this example, the third inductor 252 (which is part of the multi-coil transformer 250) is used instead of the impedance-matching inductor 852 of FIG. 9 (e.g., to further reduce area). In this example, the first terminal 251 of the third inductor 252 is coupled to the antenna 105 and the second terminal 253 of the third inductor 252 is coupled to the input 122 of the LNA 120, as discussed above. The switch 960 is coupled between the input 122 of the LNA 120 and the first terminal 723 of the source degeneration inductor 724. The switch 960 is also coupled between the second terminal 253 of the third inductor 252 and the first terminal 723 of the source degeneration inductor 724.

In the transmit mode, the controller 370 turns on (i.e., closes) the switch 960 to couple the source degeneration inductor 724 to the third inductor 252. In this mode, the source degeneration inductor 724 performs the function of the leakage inductor 334 discussed above. In the receive mode, the controller 370 turns off (i.e., opens) the switch 960. In this mode, the source degeneration inductor 724 provides the LNA 120 with source degeneration (e.g., to improve linearity and matching of the LNA 120).

The exemplary implementation illustrated in FIG. 10 may provide more area savings while the exemplary implementation illustrated in FIG. 9 may provide better PA 110 performance and LNA performance.

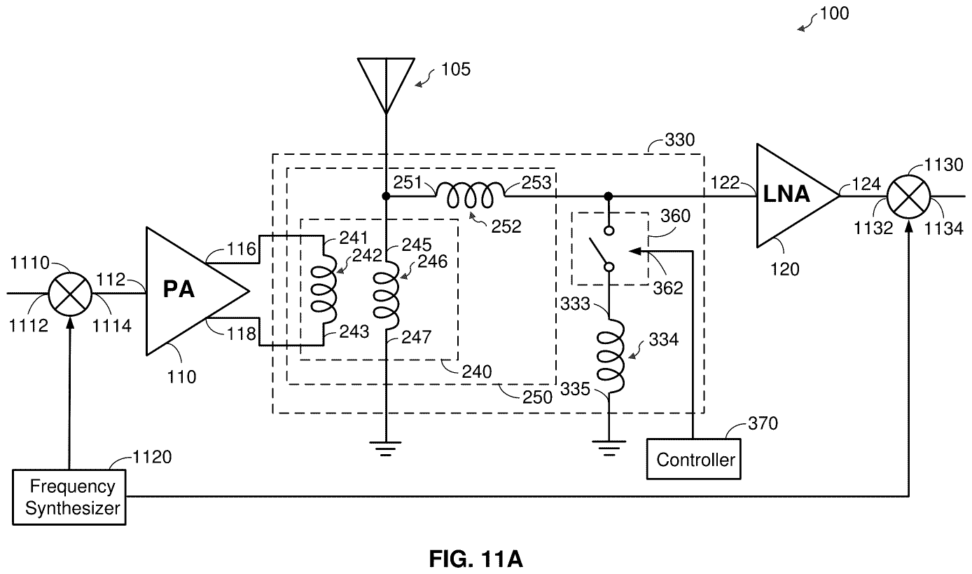

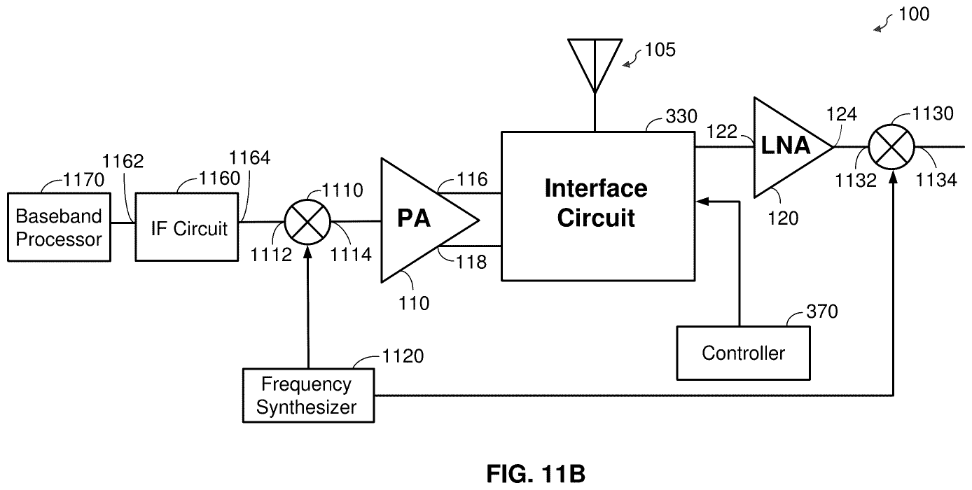

FIG. 11A shows an example in which the wireless device 100 includes a first mixer 1110, a second mixer 1130, and a frequency synthesizer 1120 according to certain aspects. The frequency synthesizer 1120 is coupled to the first mixer 1110 and the second mixer 1130. The frequency synthesizer 1120 may be implemented with one or more phase-locked loops or another type of frequency synthesizer.

In this example, the first mixer 1110 has an input 1112 and an output 1114, in which the output 1114 is coupled to the input 112 of the PA 110. The frequency synthesizer 1120 is configured to generate a first local oscillator (LO) signal and output the first LO signal to the first mixer 1110. The first mixer 1110 is configured to receive a baseband signal or an intermediate frequency (IF) signal at the input 1112, mix the baseband signal or the IF signal with the first LO signal to frequency up-convert the baseband signal or the IF signal into an RF signal, and output the RF signal to the input 112 of the PA 110. It is to be appreciated that the wireless device 100 may include one or more additional components between the first mixer 1110 and the PA 110 not shown in FIG. 11A.

In this example, the second mixer 1130 has an input 1132 and an output 1134, in which the input 1132 is coupled to the output 124 of the LNA 120. The output 1134 may be coupled to one or more filters, an IF circuit, a baseband processor, one or more amplifiers, etc. The frequency synthesizer 1120 is configured to generate a second LO signal and output the second LO signal to the second mixer 1130. The second mixer 1130 is configured to receive the amplified RF signal from the LNA 120 at the input 1132, mix the amplified RF signal with the second LO signal to frequency down-convert the amplified RF into a baseband signal or an IF signal, and output the baseband signal or the IF signal at the output 1134. It is to be appreciated that the wireless device 100 may include one or more additional components between the LNA 120 and the second mixer 1130 not shown in FIG. 11A.

FIG. 11B shows an example in which the wireless device 100 includes an IF circuit 1160 according to certain aspects. In this example, the IF circuit 1160 has an input 1162 coupled to a baseband processor 1170, and an output 1164 coupled to the input 1112 of the first mixer 1110. In this example, the baseband processor 1170 is configured to output a baseband signal to the input 1162 of the IF circuit 1160. For example, the baseband processor 1170 may receive data and/or control information and process the data and/or control information into the baseband signal. The processing may include modulation, coding, etc.

The IF circuit 1160 is configured to receive the baseband signal at the input 1162, convert the baseband signal into an IF signal, and output the IF signal at the output 1164. For example, the IF circuit 1160 may convert the baseband signal into the IF signal by frequency upconverting the baseband signal (e.g., using one or more mixers). The first mixer 1110 then mixes the IF signal with the first LO to upconvert the IF signal to the RF signal discussed above. In this example, the IF signal has an intermediate frequency that is between baseband and the frequency of the RF signal.

It is to be appreciated that the IF circuit 1160 may be omitted in some implementations. In these implementations, the first mixer 1110 may directly upconvert the baseband signal from the baseband processor 1170 into the RF signal.

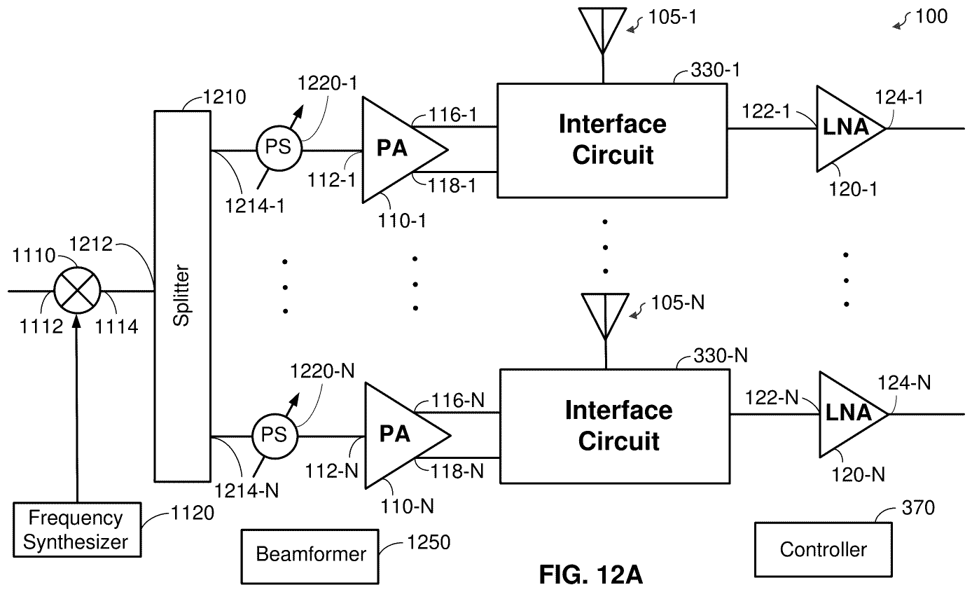

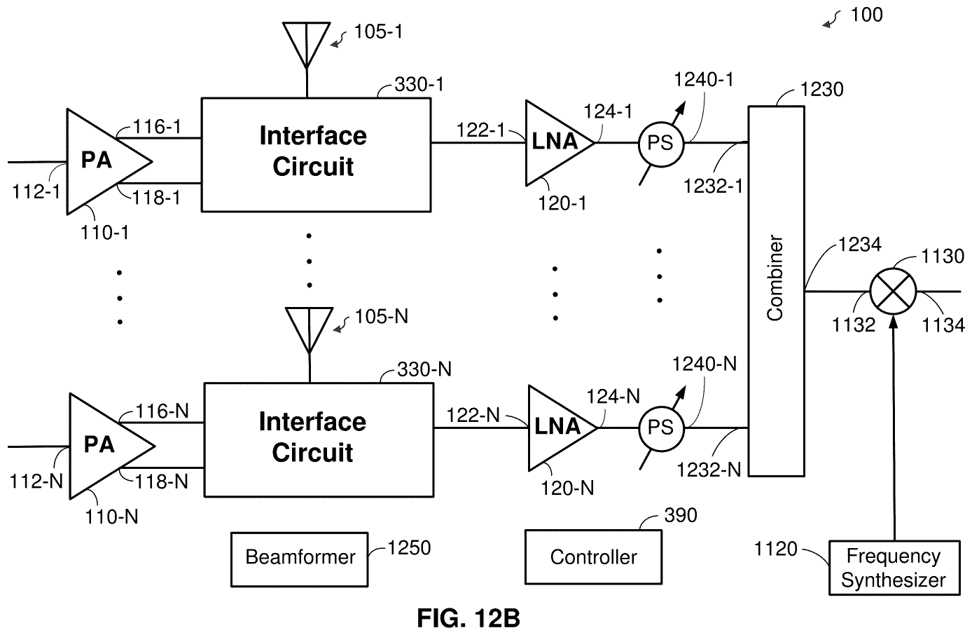

FIG. 12A shows an example in which the wireless device 100 includes multiple antennas 105-1 to 105-N according to certain aspects. The multiple antennas 105-1 to 105-N may be part of an antenna array that facilitates directional RF transmission and RF reception using beamforming.

In this example, the wireless device 100 includes multiple PAs 110-1 to 110-N, multiple LNAs 120-1 to 120-N, and multiple interface circuits 330-1 to 330-N. Each of the interface circuits 330-1 to 330-N may be implemented with the example interface circuit 330 according to any of the aspects discussed above (i.e., each of the interface circuits 330-1 to 330-N may be a separate instance of the interface circuit 330). Each of the interface circuits 330-1 to 330-N is coupled to a respective one of the antennas 105-1 to 105-N. Each of the LNAs 120-1 to 120-N may be implemented with the LNA 120 discussed above (i.e., each of the LNAs may be a separate instance of the LNA 120).

In this example, each of the interface circuits 330-1 to 330-N couples the respective one of the antennas 105-1 to 105-N to a respective one of the PAs 110-1 to 110-N and a respective one of the LNAs 120-1 to 120-N. As shown in FIG. 12A, the differential output (i.e., first output 116-1 and second output 118-1) of each of the PAs 110-1 to 110-N is coupled to the respective one of the interface circuits 330-1 to 330-N, and the input 122-1 to 122-N of each of the LNAs 120-1 to 120-N is coupled to the respective one of the interface circuits 330-1 to 330-N.

The controller 370 is coupled to the control input 362 of the switch 360 (not shown in FIG. 12A) in each of the interface circuits 330-1 to 330-N. For ease of illustration, the individual connections between the controller 370 and the interface circuits 330-1 to 330-N are not shown in FIG. 12A. In this example, the controller 370 is configured to turn on the switch 360 in each of the interface circuits 330-1 to 330-N in the transmit mode and turn off the switch 360 in each of the interface circuits 330-1 to 330-N in the receive mode.

In this example, the wireless device 100 also includes a splitter 1210 (also referred to as a divider) and multiple phase shifters 1220-1 to 1220-N for beamforming. The splitter 1210 has an input 1212 and multiple outputs 1214-1 to 1214-N. The input 1212 of the splitter 1210 is coupled to the output 1114 of the first mixer 1110. Each of the phase shifters 1220-1 to 1220-N is coupled between a respective one of the outputs 1214-1 to 1214-N of the splitter 1210 and the input 112-1 to 112-N of a respective one of the PAs 110-1 to 110-N.

In the transmit mode, the splitter 1210 is configured to receive an RF signal at the input 1212 from the first mixer 1110. As discussed above, the first mixer 1110 mixes a baseband signal or an IF signal with the first LO signal from the frequency synthesizer 1120 to generate the RF signal. The splitter 1210 is configured to split the RF signal and output the RF signal at each of the outputs 1214-1 to 1214-N. Each of the phase shifters 1220-1 to 1220-N is configured to shift the phase of the respective RF signal by a respective phase. The phase shifts of the phase shifters 1220-1 to 1220-N are controlled by a beamformer 1250 to achieve a desired transmit beam direction for the antenna array that includes the antennas 105-1 to 105-N. For ease of illustration, the individual connections between the beamformer 1250 and the phase shifters 1220-1 to 1220-N are not shown in FIG. 12A.

Each of the PAs 110-1 to 110-N amplifies the phase-shifted RF signal from the respective one of the phase shifters 1220-1 to 1220-N and outputs the resulting amplified RF signal to the respective one of the interface circuits 330-1 to 330-N. Each of the interface circuits 330-1 to 330-N couples the respective amplified RF signal to the respective one of the antennas 105-1 to 105-N for transmission.

FIG. 12B shows an example in which the wireless device 100 also includes a combiner 1230 and multiple phase shifters 1240-1 to 1240-N for beamforming. The combiner 1230 has multiple inputs 1232-1 to 1232-N and an output 1234. Each of the phase shifters 1240-1 to 1240-N is coupled between the output 124-1 to 124-N of a respective one of the LNAs 120-1 to 120-N and a respective one of the inputs 1232-1 to 1232-N of the combiner 1230. The output 1234 of the combiner 1230 is coupled to the input 1132 of the second mixer 1130.

In the receive mode, each of the LNAs 120-1 to 120-N is configured to receive an RF signal from the respective one of the antennas 105-1 to 105-N via the respective one of the interface circuits 330-1 to 330-N, amplify the respective RF signal, and output the respective amplified RF signal to the respective one of the phase shifters 1240-1 to 1240-N. Each of the phase shifters 1240-1 to 1240-N is configured to shift the phase of the respective amplified RF signal by a respective phase. The phase shifts of the phase shifters 1240-1 to 1240-N are controlled by the beamformer 1250 to achieve a desired receive beam direction for the antenna array that includes the antennas 105-1 to 105-N. For ease of illustration, the individual connections between the beamformer 1250 and the phase shifters 1240-1 to 1240-N are not shown in FIG. 12B.

The combiner 1230 is configured to receive the phase-shifted RF signals at the inputs 1232-1 to 1232-N, combine the phase-shifted RF signals into a combined RF signal, and output the combined RF signal at the output 1234. The second mixer 1130 is configured to receive the combined RF signal at the input 1132 and mix the combined RF signal with the second LO signal from the frequency synthesizer 1120 to generate a baseband signal or an IF signal at the output 1134.

It is to be appreciated that the transmit paths and the receive paths in the wireless device 100 may share components (e.g., to reduce area). For example, in some implementations, the phase shifters 1240-1 to 1240-N in FIG. 12B may be the same as the phase shifters 1220-1 to 1220-N in FIG. 12A. In these implementations, the wireless device 100 may include switches (not shown) configured to couple the phase shifters 1220-1 to 1220-N between the splitter 1210 and the PAs 110-1 to 110-N in the transmit mode and couple the phase shifters 1220-1 to 1220-N between the LNAs 120-1 to 120-N and the combiner 1230 in the receive mode. Similarly, the second mixer 1130 may be the same as the first mixer 1110 is some implementations. In these implementations, the wireless device 100 may include switches (not shown) configured to couple the first mixer 1110 to the splitter 1210 in the transmit mode and couple the first mixer 1110 to the combiner 1230 in the receive mode.

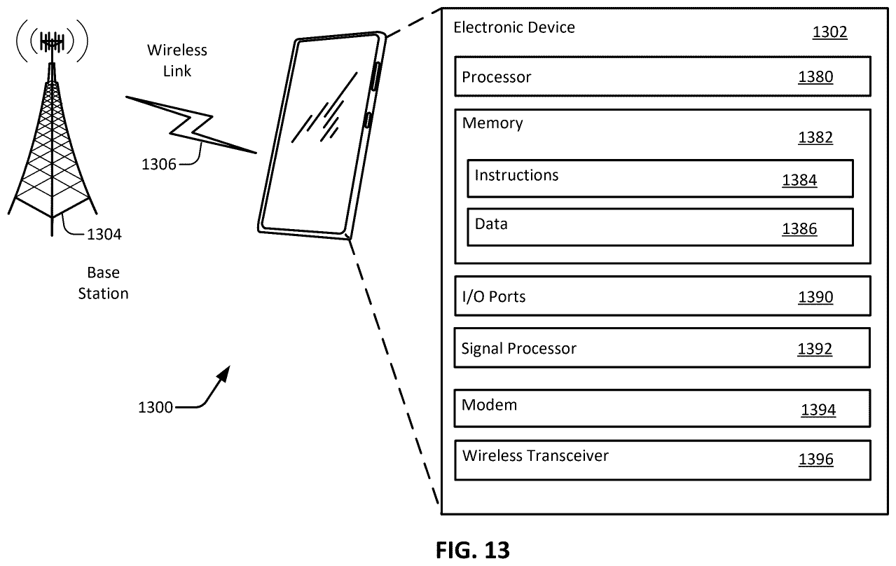

FIG. 13 is a diagram of an environment 1300 that includes an electronic device 1302 and a base station 1304. The electronic device 1302 may correspond to wireless device 100. The electronic device 1302 includes a wireless transceiver 1396, which may include the PA 110, the PAs 110-1 to 110-N, the LNA 120, the LNAs 120-1 to 120-N, the interface circuit 330, the interface circuits 330-1 to 330-N, the first mixer 1110, the frequency synthesizer 1120, the IF circuit 1160, the controller 370, the splitter 1210, the phase shifters 1220-1 to 1220-N, the beamformer 1250, the phase shifters 1240-1 to 1240-N, the combiner 1230, and/or the second mixer 1130.

In the environment 1300, the electronic device 1302 communicates with the base station 1304 via a wireless link 1306. As shown, the electronic device 1302 is depicted as a smart phone. However, the electronic device 1302 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, to name a few.

The base station 1304 communicates with the electronic device 1302 via the wireless link 1306, which may be implemented as any suitable type of wireless link. Although depicted as a base station tower of a cellular radio network, the base station 1304 may represent or be implemented as another device, such as a satellite, terrestrial broadcast tower, access point, peer to peer device, mesh network node, fiber optic line, another electronic device generally as described above, and so forth. Hence, the electronic device 1302 may communicate with the base station 1304 or another device via a wired connection, a wireless connection, or a combination thereof. The wireless link 1306 can include a downlink of data or control information communicated from the base station 1304 to the electronic device 1302 and an uplink of other data or control information communicated from the electronic device 1302 to the base station 1304. The wireless link 1306 may be implemented using any suitable communication protocol or standard, such as 3rd Generation Partnership Project Long-Term Evolution (3GPP LTE, 3GPP NR 5G), IEEE 1002.11, IEEE 1002.11, Bluetooth™, and so forth.

The electronic device 1302 includes a processor 1380 and a memory 1382. The memory 1382 may be or form a portion of a computer readable storage medium. The processor 1380 may include any type of processor, such as an application processor or a multi-core processor, which is configured to execute processor-executable instructions (e.g., code) stored by the memory 1382. The memory 1382 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the memory 1382 is implemented to store instructions 1384, data 1386, and other information of the electronic device 1302.

The electronic device 1302 may also include input/output (I/O) ports 1390. The I/O ports 1390 enable data exchanges or interaction with other devices, networks, or users or between components of the device.

The electronic device 1302 may further include a signal processor (SP) 1392 (e.g., such as a digital signal processor (DSP)). The signal processor 1392 may function similar to the processor 1380 and may be capable of executing instructions and/or processing information in conjunction with the memory 1382. The signal processor 1392 may include the baseband processor 1170.

For communication purposes, the electronic device 1302 also includes a modem 1394, the wireless transceiver 1396, and one or more antennas (e.g., antenna 105 and/or antennas 105-1 to 105-N). The wireless transceiver 1396 provides connectivity to respective networks and other electronic devices connected therewith using RF wireless signals. The wireless transceiver 1396 may facilitate communication over any suitable type of wireless network, such as a wireless local area network (LAN) (WLAN), a peer to peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN), to name a few.

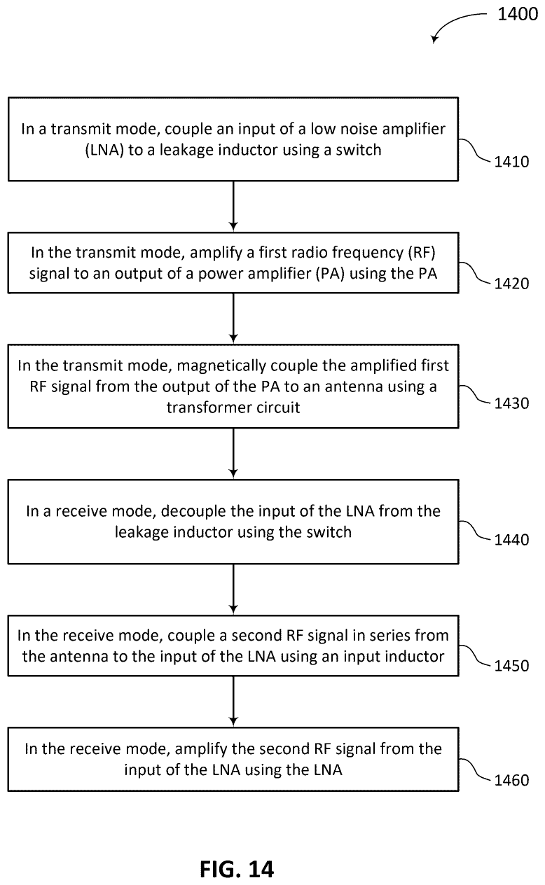

FIG. 14 illustrates a method 1400 for operating a transceiver according to certain aspects. The transceiver includes an antenna (e.g., antenna 105), a power amplifier (e.g., PA 110), a low-noise amplifier (e.g., LNA 120), and an interface circuit (e.g., interface circuit 330). The interface circuit includes a transformer circuit (e.g., PA transformer 240) magnetically coupling an output of the PA (e.g., the first and second outputs 116 and 118) to the antenna, an input inductor (e.g., inductor 252 or 852) coupling the antenna in series to an input of the LNA (e.g., input 122), and a switch (e.g., switch 360 or 960) selectively coupling the input of the LNA to a leakage inductor (e.g., leakage inductor 134, leakage inductor 334, or the source degeneration inductor 724).

At block 1410, in a transmit mode, the input of the LNA is coupled to the leakage inductor using the switch. In these aspects, coupling the input of the LNA to the leakage inductor may include turning on the switch. For example, the controller 370 may turn on the switch 360 in the transmit mode.

At block 1420, in the transmit mode, a first radio frequency (RF) signal is amplified to the output of the PA using the PA. For example, the PA 110 may receive the first RF signal at the input 112 and amplify the first RF signal to the differential PA outputs 116 and 118.

At block 1430, in the transmit mode, the amplified first RF signal is magnetically coupled from the output of the PA to the antenna using the transformer circuit. For example, the amplified first RF signal may be coupled from the first and second outputs 116 and 118 of the PA 110 (e.g., differential output of the PA 110) to the antenna 105 via magnetic coupling between the two inductors (e.g., first inductor 242 and second inductor 246) of the PA transformer 240.

At block 1440, in a receive mode, the input of the LNA is decoupled from the leakage inductor. In these aspects, decoupling the input of the LNA from the leakage inductor may include turning off the switch. For example, the controller 370 may turn off the switch 360 in the receive mode.

At block 1450, in the receive mode, a second RF signal is coupled in series from the antenna to the input of the LNA through the input inductor. For example, the second RF signal may be coupled in series from the antenna 105 to the LNA 120 using the third inductor 252 of the multi-coil transformer 250 or the impedance-matching inductor 852, both of which are coupled is series between the antenna and the input of the LNA.

At block 1460, in the receive mode, the second RF signal is amplified from the input of the LNA using the LNA. For example, the LNA 120 may receive the second RF signal at the input 122 and amplify the received second RF signal.

Implementation examples are described in the following numbered clauses:
1. An apparatus comprising:
   a power amplifier (PA);
   a low-noise amplifier (LNA); and
   an interface circuit configured to couple an antenna to the PA and the LNA, the interface circuit comprising:
      a transformer circuit configured to magnetically couple an output of the PA to the antenna;
      an input inductor coupled in series between the antenna and an input of the LNA; and
         a switch configured to selectively couple the input of the LNA to a leakage inductor.
2. The apparatus of clause 1, wherein:
   during a transmit mode, the switch couples the input of the LNA to the leakage inductor, the PA amplifies an output signal, and the transformer circuit magnetically couples the amplified output signal from the output of the PA to the antenna; and
   during a receive mode, the switch decouples the input of the LNA from the leakage inductor, and the LNA amplifies an input signal received from the antenna through the input inductor.
3. The apparatus of clause 2, further comprising a controller configured to close the switch during the transmit mode and open the switch during the receive mode.
4. The apparatus of any one of clauses 1 to 3, wherein the output of the PA includes a first output and a second output, and transformer circuit comprises:
   a first inductor coupled between the first output of the PA and the second output of the PA; and
   a second inductor coupled between the antenna and a ground, wherein the second inductor is magnetically coupled with the first inductor.
5. The apparatus of any one of clauses 1 to 4, wherein:
   the interface circuit comprises a tricoil circuit including the input inductor and two magnetically coupled inductors of the transformer circuit; and
      in a circuit layout of the tricoil circuit, the transformer circuit has an encompassing shape extending to a periphery of the tricoil circuit, the input inductor is a symmetric inductor on an inside of and surrounded by the transformer circuit, and the input inductor has a symmetric shape configured to cancel out magnetic coupling effects from the surrounding transformer circuit.
6. The apparatus of clause 5, wherein the input inductor further has a figure-eight shape.
7. The apparatus of any one of clauses 1 to 6, wherein the interface circuit includes the leakage inductor.
8. The apparatus of any one of clauses 1 to 7, wherein the leakage inductor comprises a source degeneration inductor of the LNA.
9. The apparatus of clause 8, wherein the LNA comprises a first transistor, wherein a gate of the first transistor is coupled to the input of the LNA, and a source of the first transistor is coupled to the source degeneration inductor.
10. The apparatus of clause 9, wherein the switch is coupled between the input of the LNA and the source of the first transistor.
11. The apparatus of clause 10, wherein the LNA further includes a second transistor, wherein a gate of the second transistor is configured to be biased by a bias voltage, a source of the second transistor is coupled to a drain of the first transistor, and a drain of the second transistor is coupled to an output of the LNA.
12. A transceiver comprising the apparatus and the antenna of any one of clauses 1 to 11, wherein:
   the antenna is coupled to the PA and the LNA through the interface circuit;
   the transformer circuit comprises a shunt inductor coupled between the antenna and a ground, and magnetically coupled to the output of the PA; and the input inductor is coupled in series between the antenna and the input of the LNA.
13. The transceiver of clause 12, wherein the antenna, the PA, the LNA, and the interface circuit are configured to process radio frequency (RF) signals for the transceiver in a millimeter (mm) wave (mmWave) band.
14. The transceiver of clause 12 or 13, wherein the antenna, the PA, the LNA, and the interface circuit are configured to process radio frequency (RF) signals for the transceiver according to a time division duplex (TDD) protocol.
15. An interface circuit for a transceiver having an antenna, a power amplifier (PA), and a low-noise amplifier (LNA), the interface circuit comprising:
   a transformer circuit including:
      a shunt inductor coupled to the antenna; and
         an output inductor for magnetically coupling an output of the PA to the shunt inductor;
      an input inductor coupled in series between the antenna and an input of the LNA; and
      a switch for selectively coupling a leakage inductor to the input of the LNA.
16. The interface circuit of clause 15, wherein:
   during a transmit mode, the switch couples the input of the LNA to the leakage inductor while the output inductor magnetically couples an amplified output signal from the output of the PA to the antenna through the shunt inductor; and
   during a receive mode, the switch decouples the input of the LNA from the leakage inductor while the input of the LNA receives an input signal in series from the antenna through the input inductor.
17. The interface circuit of clause 15 or 16, further comprising a tricoil circuit including the transformer circuit and the input inductor, wherein in a circuit layout of the tricoil circuit, the transformer circuit has an encompassing shape extending to a periphery of the tricoil circuit, the input inductor is a symmetric inductor on an inside of and surrounded by the transformer circuit, and the input inductor has a symmetric shape for canceling out magnetic coupling effects from the surrounding transformer circuit.
18. The interface circuit of clause 17, wherein in the circuit layout of the tricoil circuit, the output inductor has an encompassing shape extending to the periphery of the tricoil circuit, the shunt inductor has an encompassing shape inside of and surrounded by the output inductor, and the input inductor further has a figure-eight shape inside of and surrounded by the shunt inductor
19. The interface circuit of any one of clauses 15 to 18, further comprising the leakage inductor.
20. The interface circuit of any one of clauses 15 to 19, wherein the leakage inductor comprises a source degeneration inductor of the LNA.
21. The interface circuit of any one of clauses 15 to 20, wherein the interface circuit is for processing radio frequency (RF) signals for the transceiver in a millimeter (mm) wave (mmWave) band according to a time division duplex (TDD) protocol.
22. A method of operating a transceiver, the transceiver including an antenna, a power amplifier (PA), a low-noise amplifier (LNA), and an interface circuit coupling the antenna to the PA and the LNA, wherein the interface circuit includes a transformer circuit magnetically coupling an output of the PA to the antenna, an input inductor coupling the antenna in series to an input of the LNA, and a switch selectively coupling the input of the LNA to a leakage inductor, the method comprising:
   during a transmit mode,
      coupling the input of the LNA to the leakage inductor using the switch,
      amplifying a first radio frequency (RF) signal to the output of the PA using the PA, and
      magnetically coupling the amplified first RF signal from the output of the PA to the antenna using the transformer circuit; and
   during a receive mode,
      decoupling the input of the LNA from the leakage inductor using the switch,
      coupling a second RF signal in series from the antenna to the input of the LNA using the input inductor, and
      amplifying the second RF signal from the input of the LNA using the LNA.
23. The method of clause 22, wherein:
   coupling the input of the LNA to the leakage inductor comprises closing the switch during the transmit mode, and
   decoupling the input of the LNA from the leakage inductor comprises opening the switch during the receive mode.
24. The method of clause 22 or 23, wherein:
   the interface circuit comprises a tricoil circuit including the input inductor and two magnetically coupled inductors of the transformer circuit, in a circuit layout of the tricoil circuit, the transformer circuit has an encompassing shape extending to a periphery of the tricoil circuit, the input inductor is a symmetric inductor on an inside of and surrounded by the transformer circuit, and the input inductor has a symmetric shape, and
   the method further comprises canceling out magnetic coupling effects at the input inductor from the surrounding transformer circuit using the symmetric shape.
25. The method of clause 24, wherein the input inductor further has a figure-eight shape, and canceling out the magnetic coupling effects at the input inductor from the surrounding transformer circuit comprises using the figure-eight shape.
26. The method of any one of clauses 22 to 24, wherein the input inductor is magnetically separated from the transformer circuit, the leakage inductor comprises a source degeneration inductor of the LNA, and coupling the input of the LNA to the leakage inductor comprises, during the transmit mode, coupling the input of the LNA to the source degeneration inductor though the switch.

It is to be appreciated that the present disclosure is not limited to the example terminology used above to describe aspects of the present disclosure. For example, an inductor of a transformer may also be referred to as a winding or another term. Also, it is to be appreciated that an inductor may be referred to as a coil even in cases where the inductor is not physically implemented with a coil. Also, it is to be appreciated that the leakage inductor 334 may be referred to as a fourth inductor and that referring to the leakage inductor 334 as the fourth inductor does not exclude the possibility of the multi-coil transformer 250 from including more than three inductors.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a DC ground or an AC ground, and thus the term “ground” covers both possibilities. An AC ground may be provided by a DC voltage. The term “having” is used herein to be open-ended.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. An apparatus comprising:
a power amplifier (PA);
a low-noise amplifier (LNA); and
an interface circuit configured to couple an antenna to the PA and the LNA, the interface circuit comprising:
a transformer circuit configured to magnetically couple an output of the PA to the antenna;
an input inductor coupled in series between the antenna and an input of the LNA; and
a switch configured to selectively couple the input of the LNA to a leakage inductor.

2. The apparatus of claim 1, wherein:
during a transmit mode, the switch couples the input of the LNA to the leakage inductor, the PA amplifies an output signal, and the transformer circuit magnetically couples the amplified output signal from the output of the PA to the antenna; and
during a receive mode, the switch decouples the input of the LNA from the leakage inductor, and the LNA amplifies an input signal received from the antenna through the input inductor.

3. The apparatus of claim 2, further comprising a controller configured to close the switch during the transmit mode and open the switch during the receive mode.

4. The apparatus of claim 1, wherein the output of the PA includes a first output and a second output, and transformer circuit comprises:
a first inductor coupled between the first output of the PA and the second output of the PA; and
a second inductor coupled between the antenna and a ground, wherein the second inductor is magnetically coupled with the first inductor.

5. The apparatus of claim 1, wherein:
the interface circuit comprises a tricoil circuit including the input inductor and two magnetically coupled inductors of the transformer circuit; and
in a circuit layout of the tricoil circuit, the transformer circuit has an encompassing shape extending to a periphery of the tricoil circuit, the input inductor is a symmetric inductor on an inside of and surrounded by the transformer circuit, and the input inductor has a symmetric shape configured to cancel out magnetic coupling effects from the surrounding transformer circuit.

6. The apparatus of claim 5, wherein the input inductor further has a figure-eight shape.

7. The apparatus of claim 1, wherein the interface circuit includes the leakage inductor.

8. The apparatus of claim 1, wherein the leakage inductor comprises a source degeneration inductor of the LNA.

9. The apparatus of claim 8, wherein the LNA comprises a first transistor, wherein a gate of the first transistor is coupled to the input of the LNA, and a source of the first transistor is coupled to the source degeneration inductor.

10. The apparatus of claim 9, wherein the switch is coupled between the input of the LNA and the source of the first transistor.

11. The apparatus of claim 10, wherein the LNA further includes a second transistor, wherein a gate of the second transistor is configured to be biased by a bias voltage, a source of the second transistor is coupled to a drain of the first transistor, and a drain of the second transistor is coupled to an output of the LNA.

12. A transceiver comprising the apparatus and the antenna of claim 1, wherein:
the antenna is coupled to the PA and the LNA through the interface circuit;
the transformer circuit comprises a shunt inductor coupled between the antenna and a ground, and magnetically coupled to the output of the PA; and
the input inductor is coupled in series between the antenna and the input of the LNA.

13. An interface circuit for a transceiver having an antenna, a power amplifier (PA), and a low-noise amplifier (LNA), the interface circuit comprising:
a transformer circuit including:
a shunt inductor coupled to the antenna; and
an output inductor for magnetically coupling an output of the PA to the shunt inductor;
an input inductor coupled in series between the antenna and an input of the LNA; and
a switch for selectively coupling a leakage inductor to the input of the LNA.

14. The interface circuit of claim 13, wherein:
during a transmit mode, the switch couples the input of the LNA to the leakage inductor while the output inductor magnetically couples an amplified output signal from the output of the PA to the antenna through the shunt inductor; and
during a receive mode, the switch decouples the input of the LNA from the leakage inductor while the input of the LNA receives an input signal in series from the antenna through the input inductor.

15. The interface circuit of claim 13, further comprising a tricoil circuit including the transformer circuit and the input inductor, wherein in a circuit layout of the tricoil circuit, the transformer circuit has an encompassing shape extending to a periphery of the tricoil circuit, the input inductor is a symmetric inductor on an inside of and surrounded by the transformer circuit, and the input inductor has a symmetric shape for canceling out magnetic coupling effects from the surrounding transformer circuit.

16. The interface circuit of claim 15, wherein in the circuit layout of the tricoil circuit, the output inductor has an encompassing shape extending to the periphery of the tricoil circuit, the shunt inductor has an encompassing shape inside of and surrounded by the output inductor, and the input inductor further has a figure-eight shape inside of and surrounded by the shunt inductor.

17. The interface circuit of claim 13, further comprising the leakage inductor.

18. The interface circuit of claim 13, wherein the leakage inductor comprises a source degeneration inductor of the LNA.

19. A method of operating a transceiver, the transceiver including an antenna, a power amplifier (PA), a low-noise amplifier (LNA), and an interface circuit coupling the antenna to the PA and the LNA, wherein the interface circuit includes a transformer circuit magnetically coupling an output of the PA to the antenna, an input inductor coupling the antenna in series to an input of the LNA, and a switch selectively coupling the input of the LNA to a leakage inductor, the method comprising:
during a transmit mode,
coupling the input of the LNA to the leakage inductor using the switch,
amplifying a first radio frequency (RF) signal to the output of the PA using the PA, and
magnetically coupling the amplified first RF signal from the output of the PA to the antenna using the transformer circuit; and
during a receive mode,
decoupling the input of the LNA from the leakage inductor using the switch,
coupling a second RF signal in series from the antenna to the input of the LNA using the input inductor, and
amplifying the second RF signal from the input of the LNA using the LNA.

20. The method of claim 19, wherein:
coupling the input of the LNA to the leakage inductor comprises closing the switch during the transmit mode, and
decoupling the input of the LNA from the leakage inductor comprises opening the switch during the receive mode.
